(19) United States
(12) Patent Application Publication
(10) Pub. No.: US 2026/0058630 A1
(43) Pub. Date: Feb. 26, 2026

(54) Harmonic Rejection Filter for a Transformer Based Matching Circuit

(71) Applicant: Apple Inc., Cupertino, CA (US)

(72) Inventors: Tarek Khedr Abdalla Mealy, San Diego, CA (US); Bo Yu, San Diego, CA (US); Zhang Jin, San Diego, CA (US); Ahmed G Radwan, Munich (DE)

(21) Appl. No.: 18/812,118

(22) Filed: Aug. 22, 2024

(51) Int. Cl. H03H 7/38; H03H 7/01; H04B 1/04

(52) U.S. Cl. CPC H03H 7/38; H03H 7/0115; H04B 1/0458; H03H 2210/025

(57) ABSTRACT

Wireless circuitry is provided that includes an antenna and an impedance matching circuit coupled to the antenna. The impedance matching circuit can include a primary coil, a first secondary coil magnetically coupled to the primary coil by a first amount of coupling, and a second secondary coil magnetically coupled to the primary coil by a second amount of coupling different than the first amount of coupling. The impedance matching circuit can further include a capacitor having a first terminal coupled to a node disposed between the first secondary coil and the second secondary coil and having a second terminal coupled to a ground power supply line. The capacitor can be configured as a harmonic rejection component for filtering spurious harmonic signals.

### FIELD

This disclosure relates generally to electronic devices, including electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Antennas are often coupled to impedance matching circuits. An impedance matching circuit is configured to provide impedance matching between an antenna and a radio-frequency front-end module. The radio-frequency front-end module can sometimes produce harmonic signals that inadvertently leak into the antenna through the matching circuit. It can be challenging to design a matching circuit for rejecting such harmonic signals for satisfying spurious emission guidelines.

### SUMMARY

An aspect of the disclosure provides wireless circuitry that includes an antenna and an impedance matching circuit coupled to the antenna. The impedance matching circuit includes a primary coil, a first secondary coil magnetically coupled to the primary coil by a first amount of coupling, and a second secondary coil magnetically coupled to the primary coil by a second amount of coupling different than the first amount of coupling. The impedance matching circuit can further include a capacitor having a first terminal coupled to a node disposed between the first secondary coil and the second secondary coil and having a second terminal coupled to a ground power supply line. The first amount of coupling between the primary coil and the first secondary coil can be greater than the second amount of coupling between the primary coil and the second secondary coil. The first secondary coil can be magnetically coupled to the second secondary coil by a third amount of coupling different (less) than the first amount of coupling.

An aspect of the disclosure provides an impedance matching circuit that includes a primary coil, a first secondary coil magnetically coupled to the primary coil by a first coupling amount, a second secondary coil magnetically coupled to the primary coil by a second coupling amount less than the first coupling amount, and a capacitor coupled to a node disposed between the first secondary coil and the second secondary coil. The primary coil, the first secondary coil, and the second secondary coil can be concentric structures. The primary coil and the first secondary coil can be overlapping, whereas the primary coil and the second secondary coil can be nonoverlapping. The primary coil can have a first footprint delineated by a first outer radius and a first inner radius, whereas the first secondary coil can have a second footprint delineated by a second outer radius equal to or less than the first outer radius and a second inner radius equal to or greater than the first inner radius. The second secondary coil can have a third footprint delineated by a third outer radius equal to or less than the first inner radius and a third inner radius less than the third outer radius. The primary coil can include windings having a first width, and the first secondary coil and the second secondary coil can each include windings having a second width less than the first width.

An aspect of the disclosure provides a matching network that includes a first coil having terminals configured to receive or output a differential signal, a second coil magnetically coupled to and overlapping with the first coil, a third coil coupled in series with the second coil and magnetically coupled to the first coil, where the first and third coils are nonoverlapping, and a harmonic rejection component coupled in parallel with the third coil. The matching network can be configured to process signals having a given frequency, and the harmonic rejection component can include a capacitor configured to reject signals having a third harmonic frequency equal to three times the given frequency. The first coil can be magnetically coupled to the second coil via a first coupling coefficient; the first coil can be magnetically coupled to the third coil via a second coupling coefficient less than the first coupling coefficient; and the second coil can be magnetically coupled to the third coil via a third coupling coefficient less than the first coupling coefficient.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having a front-end module in accordance with some embodiments.

FIG. 3 is a diagram showing how an illustrative matching circuit configured to provide harmonic rejection can be coupled between an antenna and a digital-to-analog converter (DAC) in accordance with some embodiments.

FIG. 4 is a circuit diagram of an illustrative transformer based matching circuit configured to provide harmonic rejection in accordance with some embodiments.

FIG. 5 is a diagram plotting in-band insertion loss as a function of a coupling coefficient between a first coil and a third coil in the transformed based matching circuit in accordance with some embodiments.

FIG. 6 is a top layout (plan) view of a matching circuit of the type shown in FIG. 4 in accordance with some embodiments.

FIG. 7 is a cross-sectional side view of the matching circuit shown in FIG. 6 in accordance with some embodiments.

FIG. 8 is a diagram plotting power transmission as a function of frequency for different types of matching circuits in accordance with some embodiments.

### DETAILED DESCRIPTION

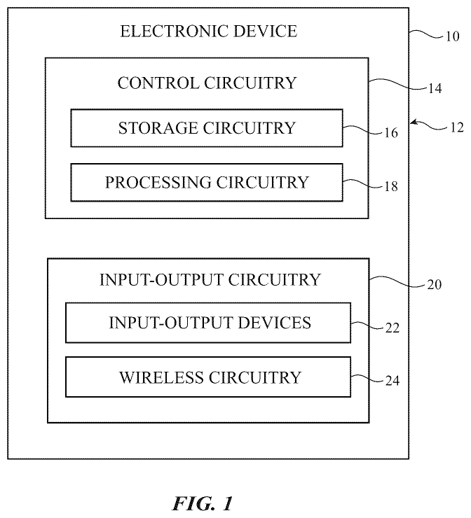

An electronic device such as device 10 of FIG. 1 may be provided with wireless circuitry. The wireless circuitry can include a matching circuit coupled between one or more antennas and a digital-to-analog converter (DAC). The digital-to-analog converter can receive a clock signal that produces harmonic signals that, if care is not taken, can propagate through to the antenna via the matching circuit. The matching circuit may be a transformer based impedance matching network (e.g., the matching circuit can include a transformer such as a balun). Such type of matching circuit can include a primary coil, a secondary coil, a third coil coupled in series with the secondary coil, and a capacitor coupled to a node disposed between the secondary coil and the third coil. The secondary coil can be magnetically coupled to the primary coil by a first coupling amount. The third coil can be magnetically coupled to the primary coil by a second coupling amount less than the first coupling amount. The third coil and the capacitor can be shunted to ground (e.g., the third coil and the capacitor can be coupled together in parallel). A matching circuit configured in this way can be technically advantageous and beneficial to reject or filter spurious harmonic signals at the antenna.

Electronic device 10 of FIG. 1 that can include such matching circuit with harmonic rejection capabilities may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), cellular sidebands, 6G bands between 100-1000 GHz (e.g., sub-THz, THz, or THF bands), etc.), other centimeter or millimeter wave frequency bands between 10-300 GHz (e.g., a short range wireless data transfer band that supports in-band full duplex communications such as a band between around 57 GHz and 64 GHz), near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

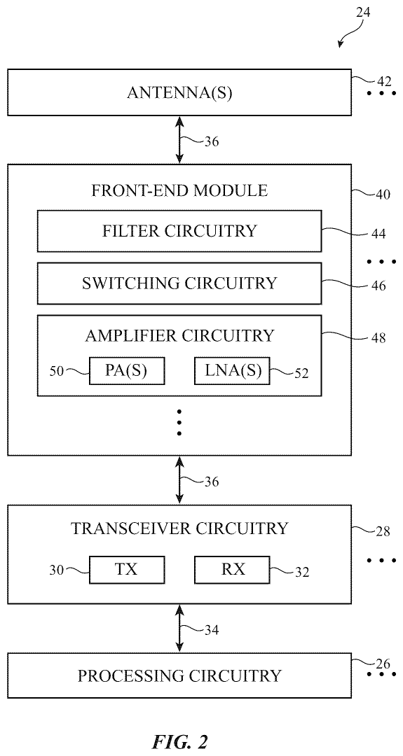

FIG. 2 is a diagram showing illustrative components within wireless circuitry 24 that can include a matching circuit configured to reject spurious harmonic signals. As shown in FIG. 2, wireless circuitry 24 may include processing circuitry such as processing circuitry 26, radio-frequency (RF) transceiver circuitry such as radio-frequency transceiver 28, radio-frequency front-end circuitry such as radio-frequency front-end module (FEM) 40, and antenna(s) 42. Processing circuitry 26 may include a baseband processor, application processor, general purpose processor, microprocessor, microcontroller, digital signal processor, host processor, application specific signal processing hardware, or other type of processor. Processing circuitry 26 may be coupled to transceiver 28 over path 34. Transceiver 28 may be coupled to antenna 42 via radio-frequency transmission line path 36. Radio-frequency front-end module 40 may be disposed on radio-frequency transmission line path 36 between transceiver 28 and antenna 42.

In the example of FIG. 2, wireless circuitry 24 is illustrated as including only a single processing unit 26, a single transceiver 28, a single front-end module 40, and a single antenna 42 for the sake of clarity. In general, wireless circuitry 24 may include any desired number of processing units 26, any desired number of transceivers 28, any desired number of front-end modules 40, and any desired number of antennas 42. Each processing unit 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front-end modules 40 may be disposed on the same radio-frequency transmission line path 36. If desired, one or more of the radio-frequency transmission line paths 36 in wireless circuitry 24 may be implemented without any front-end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processing circuitry 26 may provide transmit signals (e.g., digital or baseband signals) to transceiver 28 over path 34. Transceiver 28 may further include circuitry for converting the transmit (baseband) signals received from processing circuitry 26 into corresponding radio-frequency signals. For example, transceiver circuitry 28 may include mixer circuitry for up-converting (or modulating) the transmit (baseband) signals to radio frequencies prior to transmission over antenna 42. The example of FIG. 2 in which processing circuitry 26 communicates with transceiver 28 is illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front-end module 40. Antenna 42 may transmit the radio-frequency signals to external wireless equipment by radiating the radio-frequency signals into free space.

Front-end module (FEM) 40 may include radio-frequency front-end circuitry that operates on the radio-frequency signals conveyed (transmitted and/or received) over radio-frequency transmission line path 36. FEM 40 may, for example, include front-end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other circuitry that operates on the radio-frequency signals transmitted and/or received by antenna 42. Each of the front-end module components may be mounted to a common (shared) substrate such as a rigid printed circuit board substrate or flexible printed circuit substrate. If desired, the various front-end module components may also be integrated into a single integrated circuit chip. If desired, amplifier circuitry 48 and/or other components in front-end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front-end module 40. For example, transceiver 28 may be formed on another substrate such as the main logic board of device 10, a rigid printed circuit board, or flexible printed circuit that is not a part of front-end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processing circuitry 26 and/or portions of transceiver 28 (e.g., a host processor on transceiver 28) may form a part of control circuitry 14. Control circuitry 14 (e.g., portions of control circuitry 14 formed on processing circuitry 26, portions of control circuitry 14 formed on transceiver 28, and/or portions of control circuitry 14 that are separate from wireless circuitry 24) may provide control signals (e.g., over one or more control paths in device 10) that control the operation of front-end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), 6G bands between 100-1000 GHz (e.g., sub-THz, THz, or THF bands), etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

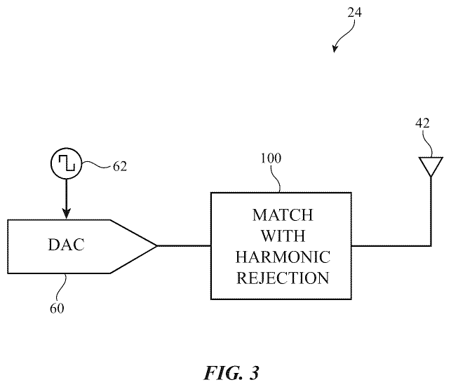

The example of wireless circuitry 24 as shown in FIG. 2 is illustrative. Wireless circuitry 24 can optionally include other components not shown in FIG. 2. FIG. 3 is a diagram showing how wireless circuitry 24 can include a matching circuit such as matching circuit 100 coupled between 42 antenna and a digital-to-analog converter (DAC) 60 in accordance with some embodiments. Matching circuit 100 may be configured to provide impedance matching between DAC 60 and antenna 42 and is therefore sometimes referred to as an impedance matching circuit or impedance matching network. Impedance matching circuit 100 can, for example, be configured to present to antenna 42 a 50 Ohm termination, a 75 Ohm termination, a 100 Ohm termination, 50-100 Ohms of termination, less than 50 Ohms of termination, greater than 100 Ohms of termination, or other impedance value to ensure optimal power transfer to antenna 42 with minimal signal reflection. Matching circuit 100 can be considered part of front-end module 40 in FIG. 2. Digital-to-analog converter 60 can be considered part of front-end module 40 or transceiver 28.

Digital-to-analog converter 60 can be a capacitive DAC (e.g., a data converter that includes one or more switchable capacitors) configured to receive an oscillating signal such as a square wave (clock) signal. The clock signal can be generated by a local clock generator 62. Any type of clock generation circuit or local oscillator can be employed for generating the clock signal. A “switchable” capacitor can refer to herein as a capacitor coupled in series with a switch that is controlled by the clock signal. Digital-to-analog converter 60 and impedance matching circuit 100 can be configured to process or output a signal at frequency f₀. Frequency f₀ can be referred to herein as a fundamental frequency. The term “harmonic” signals can refer to signals having a frequency that is equal to some integer multiple of an associated fundamental frequency. Such type of capacitive DAC that receives a square wave clock signal can produce undesired harmonic signals such as third harmonic signals (e.g., spurious signals at third harmonic frequency 3* f₀). Such spurious emission, if coupled to the antenna, can be problematic.

In accordance with an embodiment, impedance matching circuit 60 can be configured with harmonic rejection capabilities (e.g., to reject undesired harmonic signals). The term “harmonic rejection” can generally refer to and be defined herein as an act of rejecting or filtering harmonic signals, which can include second harmonic signals with a second harmonic frequency 2* f₀, third harmonic signals with a third harmonic frequency 3* f₀, fourth harmonic signals with a fourth harmonic frequency 4* f₀, fifth harmonic signals with a fifth harmonic frequency 5* f₀, and other higher order harmonic signals.

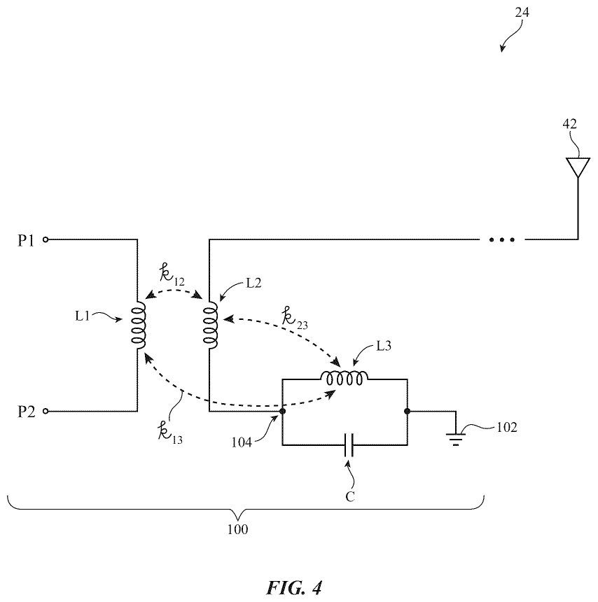

FIG. 4 is a circuit diagram showing an implementation of matching circuit 100 configured to provide harmonic rejection. As shown in FIG. 4, matching circuit 100 can include a first coil L1, a second coil L2, a third coil L3, and a capacitor C. The first coil L1 can have a first terminal coupled to terminal P1 and a second opposing terminal coupled to terminal P2. Terminals P1 and P2 can, for example, be coupled to DAC 60 (as shown in the example of FIG. 3) or other radio-frequency front-end component. The second coil L2 can have a first terminal coupled to antenna 42 (e.g., via one or more optional intervening components) and a second terminal coupled to node 104. Coils L1 and L2 can be considered part of a transformer. In particular, coil L1 can be considered a primary coil (winding) of the transformer, whereas coil L2 can be considered a secondary coil (winding) of the transformer. Coil L1 can be magnetically coupled to coil L2 via a coupling coefficient k₁₂.

The third coil L3 can have a first terminal coupled to node 104 and a second terminal coupled to ground power supply line 102 (e.g., a ground power supply terminal on which a ground voltage is provided). Coils L2 and L3 can be considered to be coupled together “in series. ” The third coil L3 can sometimes be considered part of the secondary coil (winding) of the transformer. In other words, the secondary coil can be referred to herein as including a first secondary coil (winding) portion L2 and a second secondary coil (winding) portion L3. Coil L2 can be magnetically coupled to coil L3 via a coupling coefficient k₂₃. Primary coil L1 can be magnetically coupled to coil L3 via a coupling coefficient k₁₃. Coils L2 and L3 can also sometimes be referred to herein as a first secondary coil and a second secondary coil, respectively.

Here, the primary side (e.g., coil L1) of the transformer may be a differential port, whereas the secondary side (e.g., coils L2 and L3) of the transformer may be a single-ended port (e.g., one end of the secondary coil is coupled to antenna 42, whereas the other end of the secondary coil is coupled to ground 102). Such type of transformer in which one side is differential while the other side is single-ended can sometimes be referred to as a “balun. ” Matching circuit 100 arranged in this way can thus be referred to herein as a transformer based impedance matching network or a balun based impedance matching network.

Capacitor C can have a first terminal coupled to node 104 and a second terminal coupled to ground 102. Connected in this way, capacitor C can be considered to be connected “in parallel” with third coil L3. Connecting capacitor C to a tapping point (e.g., node 104) along the secondary coil side can provide rejection or filtering of undesired harmonic signals. Capacitor C is thus sometimes referred to and defined herein as a harmonic rejection component or harmonic filter component. If care is not taken, however, a harmonic rejection capacitor can introduce undesired in-band signal loss due to its capacitive loading effects.

In accordance with an embodiment, coils L1 and L2 should be configured with a coupling coefficient k₁₂ that is greater than coupling coefficients k₂₃ and k₁₃ (e.g., k₁₂>k₂₃ and k₁₂>k₁₃). Coupling coefficient k₂₃ can be equal to or different than coupling coefficient k₁₃. As an example, coupling coefficient k₁₃ and k₂₃ can each be equal to around 0.4, whereas coupling coefficient k₁₂ can be equal to 0.7 or some other value greater than 0.4. As another example, coupling coefficient k₁₃ can be equal to 0.4, coupling coefficient k₂₃ can be equal to 0.3, and coupling coefficient k₁₂ can be equal to 0.8 or some other value greater than 0.4. These examples are illustrative. Having harmonic rejection capacitor C coupled in parallel with coil L3 that is weakly coupling to primary coil L1 (relative to the coupling between L1 and L2) can be technically advantageous and beneficial to help mitigate the in-band signal loss introduced from capacitor C. Capacitor C and coil L3 configured to operate in this way are thus sometimes referred to collectively herein as a harmonic rejection tank.

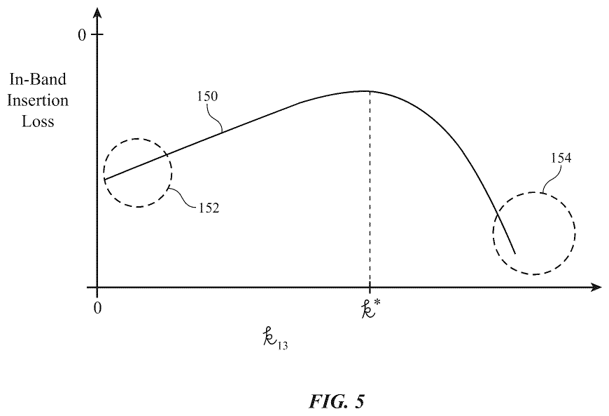

The coupling coefficient k₁₃ between coils L1 and L3 can be optimized. FIG. 5 is a diagram plotting an in-band insertion loss profile 150 as a function of coupling coefficient k₁₃ between coils L1 and L3. As shown in region 152 of FIG. 5, when the coupling coefficient k₁₃ is too low (e.g., near 0, near 0.1, near 0.2, less than 0.4, less than 0.3, less than 0.2, or less than 0.1), the in-band insertion loss can be degraded due to a reduced quality (Q) factor of the transformer based matching circuit due to low coupling values between the rejection tank inductance L3 and coils L1 and L2. At the other extreme as shown in region 154, when the coupling coefficient k₁₃ is too high (e.g., greater than 0.4, greater than 0.5, greater than 0.6, or greater than 0.7), the in-band insertion loss can also be degraded due to the requirement for a larger capacitor C. Thus, coupling coefficient k₁₃ should have a value k* corresponding to a point in profile 150 that minimizes the in-band insertion loss. As examples, the optimal coupling k* value can be equal to 0.3, 0.4, 0.5, 0.3-0.5, or other value providing a moderate amount of magnetic coupling between coils L1 and L3.

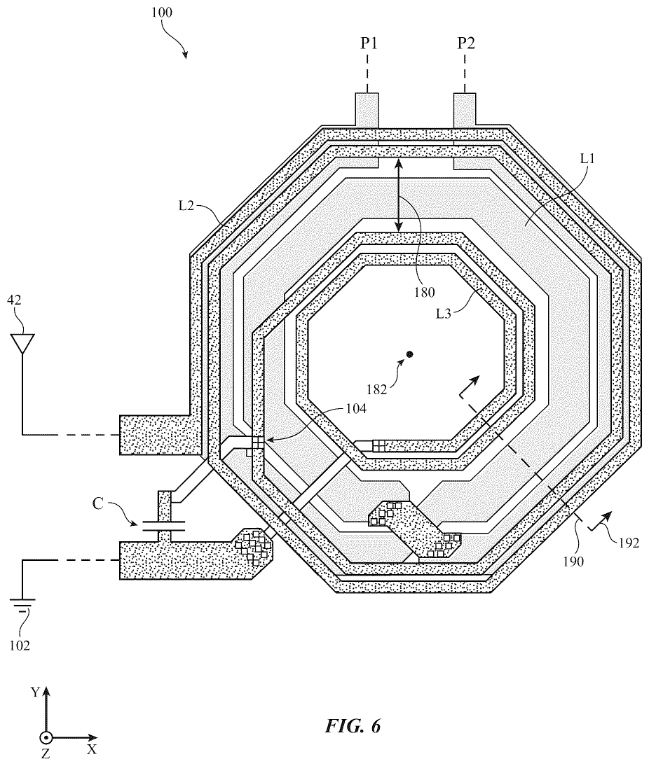

FIG. 6 is a top layout (plan) view of a matching circuit 100 of the type described in connection with FIG. 4. As shown in FIG. 6, the primary coil L1 may be formed in a first metal routing layer and can have a first terminal coupled to terminal P1 and a second terminal coupled to terminal P2. Terminals P1 and P2 can serve collectively as a differential port configured to receive or output differential signals. In the example of FIG. 6, primary coil L1 has two turns and an octagonal footprint. This is illustrative. In general, primary coil L1 can have any number of turns and can have a footprint of any shape.

The secondary side of the transformer (balun) can include the second coil (portion) L2 and the third coil (portion) L3 that are formed in a second metal routing layer different than the first metal routing layer. The second metal routing layer can be disposed above or below the first metal routing layer. As shown in FIG. 4, coil L2 has a first terminal coupled to antenna 412 and a second terminal coupled to node 104. Although coil L2 of FIG. 6 is shown with two turns and an octagonal footprint, coil L2 can have any number of turns and a footprint of any shape. In particular, coil L2 is configured to overlap with primary coil L1 (e.g., coil L2 is formed directly on top of or below coil L1). Such overlapping yields the higher coupling coefficient k₁₂ described above in connection with FIG. 4. Filter (rejection) capacitor C can have a first terminal coupled to node 104 and a second terminal coupled to ground line 102. Capacitor C can be implemented as a metal-oxide-semiconductor (MOS) capacitor, a metal-insulator-metal (MIM) capacitor, a metal-oxide-metal (MOM) capacitor, a polysilicon-insulator-polysilicon (PIP) capacitor, a trench capacitor (e.g., a capacitor formed by filling a trench with conductive and high-k dielectric material), and/or other types of integrated capacitors.

Lastly, coil L3 has a first terminal coupled to node 104 and a second terminal coupled to ground line 102. Although coil L3 of FIG. 6 is shown with two turns and an octagonal footprint, coil L3 can have any number of turns and a footprint of any shape. In particular, coil L3 is configured with minimal overlapping with primary coil L1 (e.g., coils L1 and L3 are “nonoverlapping”). In other words, the windings of primary coil L1 can have a center region that is devoid of any L1 winding as shown in FIG. 6, and coil L3 can have a footprint that is equal to or smaller than the center region of coil L1. Such lack of overlapping between coils L1 and L3 yields the lower coupling coefficient k₁₃ described above in connection with FIG. 4. Moreover, as shown in FIG. 6, the secondary coils L2 and L3 can be formed in the same metal routing layer and separated by a distance 180. Such an extended gap between coils L2 and L3 yields the lower coupling coefficient k₂₃ described above in connection with FIG. 4.

Still referring to FIG. 6, coils L1, L2, and L3 are concentric coil structures (e.g., coils L1, L2, and L3 all share a common center point 182). The primary coil L1 can have windings formed within a first footprint delineated by a first outer radius and a first inner radius. The first secondary coil L2 can have windings formed within a second footprint delineated by a second outer radius and a second inner radius. The second outer radius of L2 can be equal to or less than the first outer radius of L1, whereas the second inner radius of L2 can be equal to or greater than the first inner radius of L1. The second secondary coil L3 can have windings formed within a third footprint delineated by a third outer radius and a third inner radius. The third outer radius of L3 can be equal to or less than the first inner radius of L1, whereas the third inner radius of L3 just has to be less than the third outer radius. The width of the windings of coils L2 and L3 can be less than the width of the windings of coil L1. The width of the windings of coil L2 can be equal to the width of the windings of coil L3. The layout of FIG. 6 is exemplary. If desired, other layout schemes can be employed to achieve the desired amount of coupling described above in connection with FIG. 4.

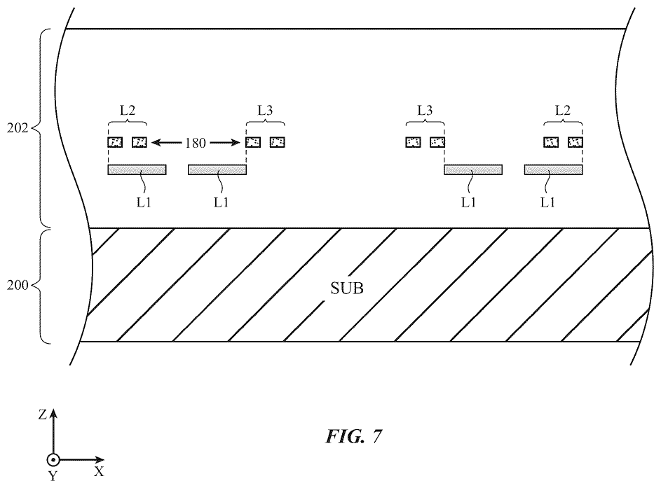

FIG. 7 is a side view of matching circuit 100 of the type described in connection with FIG. 6 (e.g., a cross-sectional side view cut along dotted line 190 and viewed in the direction of arrow 192). As shown in FIG. 7, an interconnect stack such as interconnect stack 202 can be formed on semiconductor substrate 202 (e.g., a p-doped silicon substrate).

Interconnect stack 202 may include alternating routing layers and via layers. Each of the routing layers can include conductive (metal) routing paths formed in a layer of dielectric material and is thus sometimes referred to as a “metal routing” layer. Each via layer can include conductive (metal) vias formed in a layer of dielectric material and is thus sometimes referred to as a “metal via”layer.

Interconnect stack 202 is therefore sometimes referred to as a dielectric stack (e.g., an interconnect stack having conductive routing structures formed within dielectric material such as silicon dioxide). The conductive routing structures formed in the metal routing layers and the conductive via structures formed in the metal via layers can be formed using copper, aluminum, tungsten, titanium, gold, silver, nickel, a metal alloy, a combination of metals, and/or other types of conductive material. The metal routing structures and the metal via structures in the dielectric stack can form an electrical network for interconnecting together various components within the integrated circuit die.

In the example of FIG. 7, primary coil L1 can be formed in a first metal routing layer, and secondary coils L2 and L3 can be formed in a second metal routing layer disposed above the first metal routing layer. This is illustrative. In other embodiments, coil L2 and/or coil L3 can alternatively be formed in a third metal routing layer that is disposed below the first metal routing layer. In yet other embodiments, coils L2 and L3 can optionally be formed in different metal routing layers. In the stackup of FIG. 7, coil L2 can be formed directly above coil L1 (e.g., coils L1 and L2 are “overlapping”). In contrast, coil L3 is not formed directly above coil L1 (e.g., coils L1 and L3 are “nonoverlapping”). If desired, the distance 180 between coils L2 and L3 can be further augmented to reduce the coupling coefficient k₂₃.

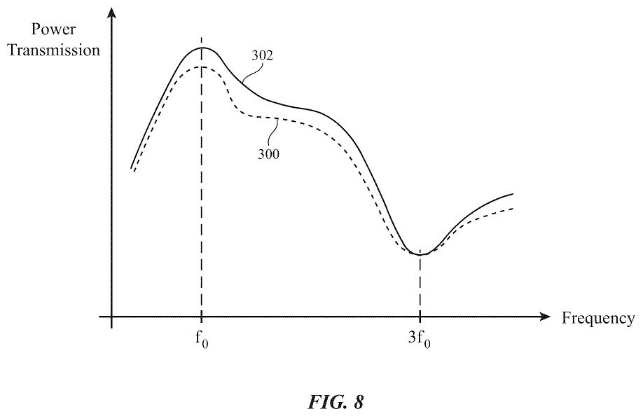

FIG. 8 is a diagram plotting power transmission as a function of frequency for different types of matching circuits. Curve 300 may represent the power transmission profile for a matching circuit that includes a harmonic rejection capacitor, but where k₁₂, k₁₃, and k₂₃ are all equal (i.e., k₁₂=k₁₃=k₂₃). Such power transmission profile can be achieved if coil L3 overlaps with coil L1. Curve 302 may represent the power transmission profile for matching circuit 100 of the type described in connection with FIGS. 1-7. As shown in the plot of FIG. 8, curves 300 and 302 can both provide harmonic rejection at third harmonic frequency 3*f₀, but curve 302 can provide improved power transmission levels at fundamental frequency f₀ and has the benefit of using a smaller capacitor value for the harmonic rejection tank. Thus, impedance matching network 100 can enable third harmonic rejection with minimal degradation to in-band insertion loss.

The methods and operations described above in connection with at least FIGS. 1-3 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is exemplary and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. Wireless circuitry comprising:
an antenna; and
an impedance matching circuit coupled to the antenna, wherein the impedance matching circuit comprises:
a primary coil;
a first secondary coil magnetically coupled to the primary coil by a first amount of coupling; and
a second secondary coil magnetically coupled to the primary coil by a second amount of coupling different than the first amount of coupling.

2. The wireless circuitry of claim 1, wherein the impedance matching circuit further comprises:
a capacitor having a first terminal coupled to a node disposed between the first secondary coil and the second secondary coil and having a second terminal coupled to a ground power supply line.

3. The wireless circuitry of claim 2, wherein the second secondary coil comprises a first terminal coupled to the first secondary coil and a second terminal coupled to the ground power supply line.

4. The wireless circuitry of claim 2, wherein the first secondary coil comprises a first terminal coupled to the antenna and a second terminal coupled to a node between the second secondary coil and the capacitor.

5. The wireless circuitry of claim 2, wherein the first amount of coupling between the primary coil and the first secondary coil is greater than the second amount of coupling between the primary coil and the second secondary coil.

6. The wireless circuitry of claim 5, wherein the first secondary coil is magnetically coupled to the second secondary coil by a third amount of coupling different than the first amount of coupling.

7. The wireless circuitry of claim 6, wherein the first amount of coupling between the primary coil and the first secondary coil is greater than the third amount of coupling between the first secondary coil and the second secondary coil.

8. The wireless circuitry of claim 6, wherein the second amount of coupling between the primary coil and the second secondary coil is equal to the third amount of coupling between the first secondary coil and the second secondary coil.

9. The wireless circuitry of claim 2, wherein the second amount of coupling is optimized for reducing in-band insertion loss for the impedance matching circuit.

10. The wireless circuitry of claim 2, wherein the impedance matching circuit is configured to process signals having a fundamental frequency, and wherein the capacitor is configured to reject harmonic signals having a frequency equal to an integer multiple of the fundamental frequency for the impedance matching circuit.

11. An impedance matching circuit comprising:
a primary coil;
a first secondary coil magnetically coupled to the primary coil by a first coupling amount;
a second secondary coil magnetically coupled to the primary coil by a second coupling amount less than the first coupling amount; and
a capacitor coupled to a node disposed between the first secondary coil and the second secondary coil.

12. The impedance matching circuit of claim 11, wherein:
the first secondary coil comprises a first terminal coupled to an antenna and a second terminal coupled to the node;
the second secondary coil comprises a first terminal coupled to the node and a second terminal coupled to a ground line; and
the second secondary coil and the capacitor are coupled in parallel.

13. The impedance matching circuit of claim 11, wherein the primary coil, the first secondary coil, and the second secondary coil comprise concentric structures.

14. The impedance matching circuit of claim 13, wherein:
the primary coil and the first secondary coil are overlapping; and
the primary coil and the second secondary coil are nonoverlapping.

15. The impedance matching circuit of claim 13, wherein:
the primary coil has a first footprint delineated by a first outer radius and a first inner radius; and
the first secondary coil has a second footprint delineated by a second outer radius equal to or less than the first outer radius and a second inner radius equal to or greater than the first inner radius.

16. The impedance matching circuit of claim 15, wherein the second secondary coil has a third footprint delineated by a third outer radius equal to or less than the first inner radius and a third inner radius less than the third outer radius.

17. The impedance matching circuit of claim 11, wherein the primary coil comprises windings having a first width and wherein the first secondary coil and the second secondary coil each comprise windings having a second width less than the first width.

18. A matching network comprising:
a first coil having terminals configured to receive or output a differential signal;
a second coil magnetically coupled to and overlapping with the first coil;
a third coil coupled in series with the second coil and magnetically coupled to the first coil, wherein the first and third coils are nonoverlapping; and
a harmonic rejection component coupled in parallel with the third coil.

19. The matching network of claim 18, wherein the matching network is configured to process signals having a given frequency, and wherein the harmonic rejection component comprises a capacitor configured to reject signals having a third harmonic frequency equal to three times the given frequency.

20. The matching network of claim 18, wherein:
the first coil is magnetically coupled to the second coil via a first coupling coefficient;
the first coil is magnetically coupled to the third coil via a second coupling coefficient less than the first coupling coefficient; and
the second coil is magnetically coupled to the third coil via a third coupling coefficient less than the first coupling coefficient.
